(19) United States
(12) Patent Application Publication
(10) Pub. No.: US 2026/0319214 A1
(43) Pub. Date: Oct. 15, 2026

(54) WAFER-LEVEL LENS, LENS UNIT, AND OPTOELECTRONIC MODULE

(71) Applicant: Triple Win Technology ( Shenzhen ) Co. Ltd., Shenzhen (CN)

(72) Inventors: HSIN-YEN HSU, New Taipei (TW); Tzu-Li Feng, New Taipei (TW); Chien-Liang Chou, New Taipei (TW)

(21) Appl. No.: 19/254,453

(22) Filed: Jun. 30, 2025

(30) Foreign Application Priority Data
Apr. 9, 2025 (CN) 202510439696.6

(51) Int. Cl. G02B 7/00; G02B 13/00; G02B 27/42; H10F 39/00

(52) U.S. Cl. CPC G02B 7/003; G02B 13/0085; G02B 27/4205; H10F 39/804; H10F 39/8063; G02B 2207/101

(57) ABSTRACT

Embodiments of the present disclosure relate to a wafer-level lens, a lens unit, and an optoelectronic module. The wafer-level lens includes a wafer-level substrate, a plurality of lenses on the wafer-level substrate, and a plurality of supporting structures the wafer-level substrate. Each supporting structure corresponds to a lens, and a projection of each supporting structure on the wafer-level substrate at least partially overlaps with the corresponding lens on the wafer-level substrate to compensate for a tilt angle of an optical axis of the corresponding lens. The wafer-level lens is beneficial to improving the production efficiency and yield of optoelectronic modules.

### FIELD

The subject matter herein generally relates to the field of optical imaging technology, and specifically to a wafer-level lens, a lens unit, and an optoelectronic module.

### BACKGROUND

In the packaging process of optoelectronic modules, precise alignment between the lens and the optoelectronic component is crucial. Traditional lens manufacturing involves assembly of a plurality of components, deviations and tilts between the actual optical path and the design values may occur during the assembly process. In high-performance optoelectronic modules, such deviations need to be corrected.

Current packaging methods for optoelectronic modules typically employ real-time imaging feedback adjustment. Specifically, while the optoelectronic component remains in operation, the tilt angle of the lens relative to the optoelectronic component is adjusted by monitoring the imaging effect in real time, to achieve optimal imaging quality. Subsequently, the relative orientation of the lens and the optoelectronic component is maintained, and adhesive is used to fix the lens to the optoelectronic component, followed by pre-curing.

However, the above described method has two primary technical bottlenecks. First, production efficiency is limited: the adhesive pre-curing requires sufficient time to ensure adequate strength to maintain the relative tilt angle between the lens and the optoelectronic component until the curing process is completed, the wait time during the pre-curing significantly limits production efficiency. Second, production yield is low: volume shrinkage inevitably occurs during the adhesive curing process, and the degree of shrinkage is influenced by the volume and thickness of the adhesive. The volume shrinkage of the adhesive causes changes in the already adjusted tilt angle of the lens relative to the optoelectronic component, thereby affecting the accuracy of tilt angle correction and ultimately reducing the production yield of optoelectronic modules.

Therefore, existing packaging methods for optoelectronic modules still have room for improvement in terms of production efficiency and yield.

### BRIEF DESCRIPTION OF THE DRAWINGS

Implementations of the present disclosure will now be described, by way of embodiment, with reference to the attached figures.

FIG. 1 is a schematic structural diagram of a wafer-level lens according to an embodiment of the present disclosure.

FIG. 2 is another schematic structural diagram of a wafer-level lens according to an embodiment of the present disclosure.

FIG. 3A is a schematic structural diagram of a supporting structure according to an embodiment of the present disclosure.

FIG. 3B is a schematic structural diagram of a supporting structure according to an embodiment of the present disclosure.

FIG. 3C is a schematic structural diagram of a supporting structure according to an embodiment of the present disclosure.

FIG. 4A is a schematic structural diagram of a supporting structure according to an embodiment of the present disclosure.

FIG. 4B is a schematic structural diagram of a supporting structure according to an embodiment of the present disclosure.

FIG. 4C is a schematic structural diagram of a supporting structure according to an embodiment of the present disclosure.

FIG. 4D is a schematic structural diagram of a supporting structure according to an embodiment of the present disclosure.

FIG. 5 is a cross-sectional schematic diagram of an optoelectronic module according to an embodiment of the present disclosure.

FIG. 6 is an exploded schematic diagram of an optoelectronic module according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein may be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series, and the like. The disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one”.

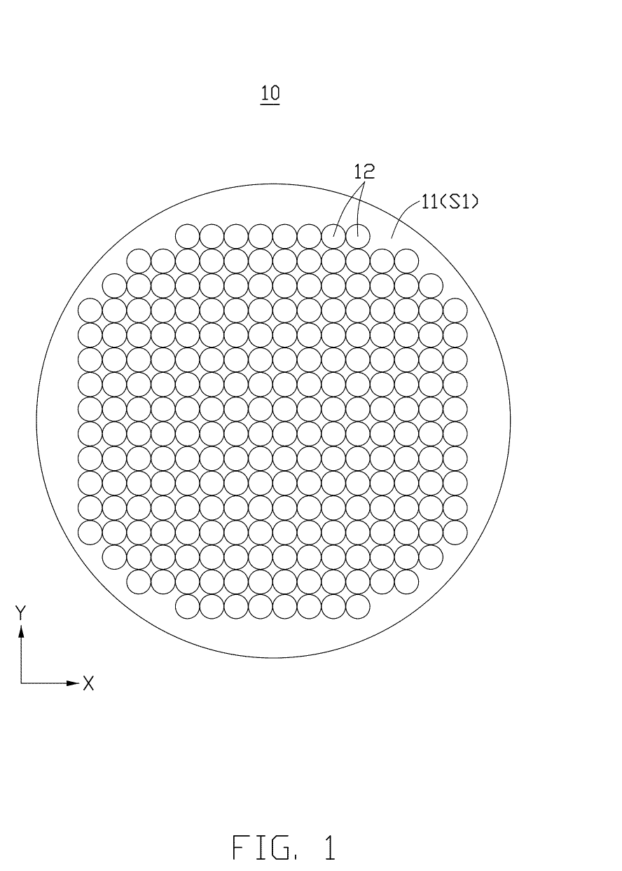

FIG. 1 is a schematic structural diagram of a wafer-level lens 10 according to an embodiment of the present disclosure. As shown in FIG. 1, the wafer-level lens 10 includes a wafer-level substrate 11 and a plurality of lenses 12 on the wafer-level substrate 11. The lenses 12 are arranged in a plurality of rows along a first direction X and in a plurality of columns along a second direction Y, where the first direction X is perpendicular to the second direction Y. For ease of description, the first direction X is also referred to as the left-right direction, and the second direction Y is referred to as the up-down direction.

It should be noted that, the term “wafer-level substrate” when utilized, means a substrate used for mass production of microelectronic devices or other microstructures. The size of the wafer-level substrate matches the standard sizes of traditional wafers (such as 200 mm, 300mm, etc.), but is not limited to specific sizes or shapes.

For example, the wafer-level substrate can be a circular substrate, a rectangular substrate, or a substrate of another shape, as long as its size can support parallel manufacturing of a plurality of microelectronic devices or microstructures, it can be considered a “wafer-level substrate.”

It should also be noted that, in the wafer-level lens 10, at least some of the plurality of lenses 12 have optical axis tilt angles that need to be compensated. The optical axis is the ideal central axis of a lens. An optical axis tilt angle (or a tilt angle of an optical axis) refers to an angular deviation between the actual optical axis of the lens and the ideal optical axis. The deviation can cause image distortion or other optical problems, and therefore needs to be compensated.

The following description will use the embodiments where the optical axis tilt angle of each lens 12 needs to be compensated.

In some embodiments, each lens 12 in the wafer-level lens 10 is selected from at least one of the following: a metalens having an array of nanostructures with sub-wavelength dimensions; a diffractive optical lens with predetermined phase modulation characteristics; a Fresnel lens with a plurality of concentric ring structures, the ring structures forming a stepped refractive surface; a gradient refractive index lens having a continuously varying refractive index distribution from center to edge; or a microlens array having a predetermined radius of curvature and refractive index.

Thus, the overall wafer-level design facilitates mass production, and the wafer-level lens 10 can be a metalens, a diffractive optical element, or various other types of lenses, providing wide applicability.

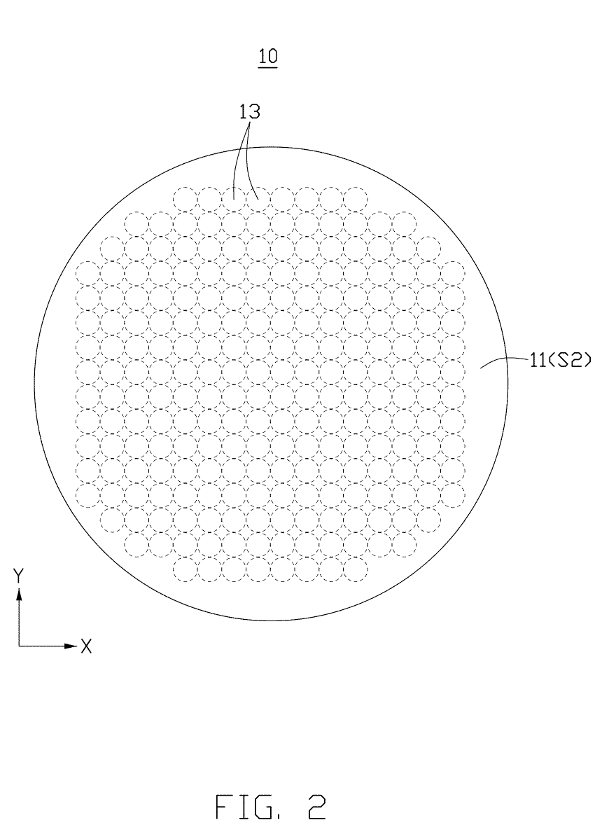

As shown in FIGS. 1 and 2, the wafer-level lens 10 further includes a plurality of supporting structures 13. The distribution of the plurality of supporting structures 13 corresponds to the distribution of the plurality of lenses 12.

Specifically, each supporting structure 13 corresponds to one lens 12 with an optical axis tilt angle that needs to be compensated, and a projection of each supporting structure 13 on the wafer-level substrate 11 at least partially overlaps with a projection of the corresponding lens 12 on the wafer-level substrate 11, to compensate for the optical axis tilt angle of the corresponding lens 12.

More specifically, the wafer-level substrate 11 includes opposite first surface S1 and second surface S2. The lenses 12 are located on the first surface S1. The supporting structures 13 are located on the second surface S2. That is, the supporting structures 13 are on a side of the wafer-level substrate 11 away from the lenses 12. Or in other words, the supporting structures 13 and the lenses 12 are on opposite sides of the wafer-level substrate 11, respectively.

In other embodiments, the supporting structures 13 and the lenses 12 are on the same side of the wafer-level substrate 11, with each supporting structures 13 formed at the edges of the corresponding lens 12 to compensate for the optical axis tilt angles of the corresponding lens 12.

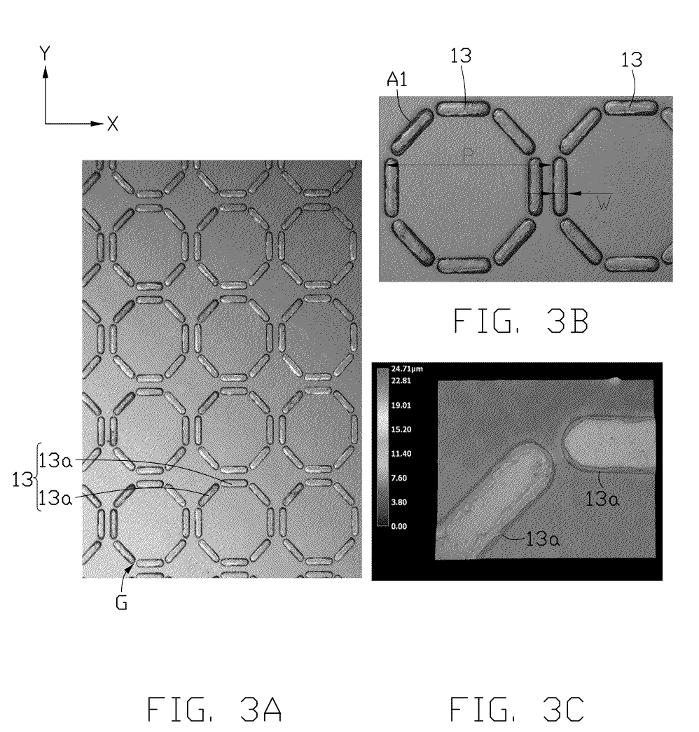

FIG. 3A is a structural schematic diagram of a supporting structure 13 according to an embodiment of the present disclosure. As shown in FIG. 3A, each supporting structure 13 has approximately the same shape. The supporting structures 13 are arranged in a plurality of rows along the first direction X and in a plurality of columns along the second direction Y.

Each supporting structure 13 has a non-closed annular structure. Specifically, each supporting structure 13 includes a plurality of sub-portions 13a spaced apart from each other along the circumferential direction of the corresponding lens 12. There is a gap G between each adjacent sub-portion 13a. Each sub-portion 13a is in the shape of a strip.

In some embodiments, each supporting structure 13 has eight sub-portions 13a, which are approximately evenly distributed at equal angles.

Specifically, with respect to the center of the supporting structure 13, the eight sub-portions 13a are positioned at the top, bottom, left, right, top-left, bottom-left, top-right, and bottom-right positions, respectively. The arrangement is beneficial for directionally compensating for the tilt of the lens 12 in multiple directions, and thereby improving imaging quality and increasing production yield.

As shown in FIG. 3B, the pitch P between adjacent supporting structures 13 matches the distance between adjacent lenses 12. The width W of each supporting structure 13 is on a micrometer scale, and each supporting structure 13 can be, but is not limited to, 120 micrometers. The pitch P between adjacent supporting structures 13 is on the millimeter scale, and the pitch P between adjacent supporting structures 13 can be, but is not limited to, 1.64mm.

In some embodiments, each supporting structure 13 has a non-uniform height distribution along the circumferential direction of the corresponding lens 12, and the non-uniform height distribution is configured to match the degree of the optical axis and a direction of the optical axis tilt angle of the corresponding lens 12.

That is, the degree of height variation and the position of height variation of each supporting structure 13 match the magnitude and direction of the optical axis tilt angle of the lens 12.

In other words, the supporting structure 13 will provide support of a specific height at a specific position based on the deviation of the lens 12, thereby counteracting or mitigating the impact of this optical axis tilt angle.

For example, if the optical axis of the lens 12 tilts to the left, the supporting structure 13 may be slightly raised on the right side of the lens 12, making the lens 12 appear more upright as a whole, thereby improving imaging quality.

In some embodiments, an overlapping area A1 is formed by overlapping the projection of the supporting structure 13 on the wafer-level substrate 11 at least partially overlaps with a projection of the corresponding lens 12 on the wafer-level substrate 11, and the overlapping area A1 is configured to compensate for the tilt angle of the optical axis of the corresponding lens 12.

In some embodiments, the boundary of the overlapping area A1 coincides with the boundary of the projection of the supporting structure 13 on the wafer-level substrate 11. In some embodiments, the overlapping area A1 partially overlaps the projection of the supporting structure 13 on the wafer-level substrate 11.

FIG. 3C illustrates the height distribution of two sub-portions 13a of a supporting structure 13. As can be seen from FIG. 3C, each sub-portion 13a has a different height. The height of the top-left sub-portion 13a is approximately 25 micrometers, while the height of the top sub-portion 13a is approximately 15 micrometers.

That is, the supporting structure 13 has a non-uniform height distribution along the circumferential direction of the lens 12, the non-uniform height distribution is configured to match with a degree of the optical axis and a direction of the tilt angle of the optical axis of the lens 12. By adjusting the height of each sub-portion 13a individually, the compensation effect can be optimized.

In other embodiments, the number and shape of sub-portions 13a in the supporting structure 13 are not limited to those described above.

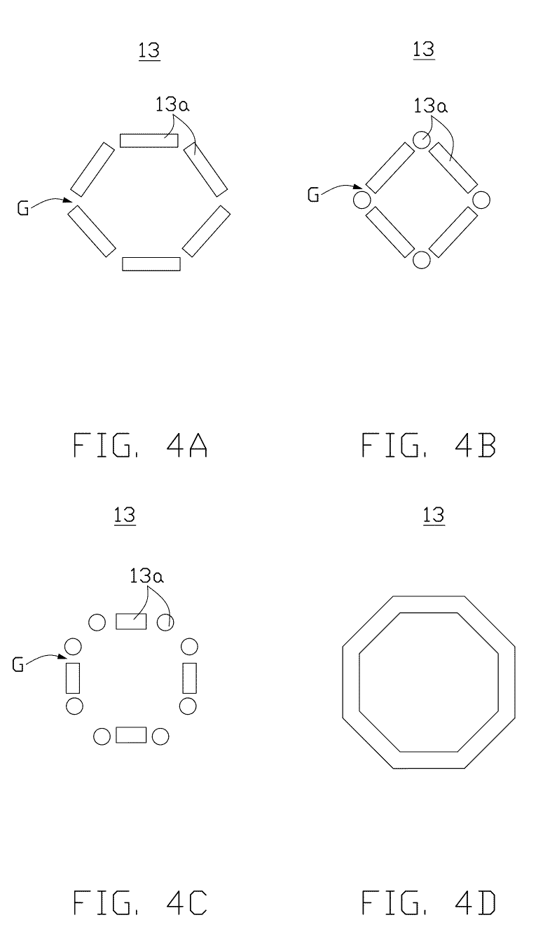

In some embodiments, as shown in FIG. 4A, the supporting structure 13 may include six sub-portions 13a approximately evenly and spaced distributed along the circumferential direction, with each sub-portion 13a in the shape of a strip.

In some embodiments, as shown in FIG. 4B, the supporting structure 13 may include eight sub-portions 13a approximately evenly and spaced distributed along the circumferential direction, including four circular sub-portions 13a and four strip-shaped sub-portions 13a. Along the circumferential direction of the supporting structure 13, the circular sub-portions 13a and the strip-shaped sub-portions 13a are alternately distributed. The four circular sub-portions 13a are positioned at the top, bottom, left, and right positions, respectively.

In some embodiments, as shown in FIG. 4C, the supporting structure 13 may include twelve sub-portions 13a approximately evenly and spaced distributed along the circumferential direction, including eight circular sub-portions 13a and four strip-shaped sub-portions 13a. Along the circumferential direction of the supporting structure 13, every two circular sub-portions 13a and one strip-shaped sub-portion 13a are alternately distributed. The eight circular sub-portions 13a are positioned at the top, bottom, left, and right positions, respectively.

In some embodiments, as shown in FIG. 4D, the supporting structure 13 is a closed annular structure. The thickness of the ring structure can vary along the circumferential direction. Specifically, the supporting structure 13 can be, but is not limited to, a closed octagonal annular structure.

In some embodiments, the more optically measurable optical tilt phase angles the lens 12 has, the closer it can reach 360-degree nearly continuous phase compensation height capability.

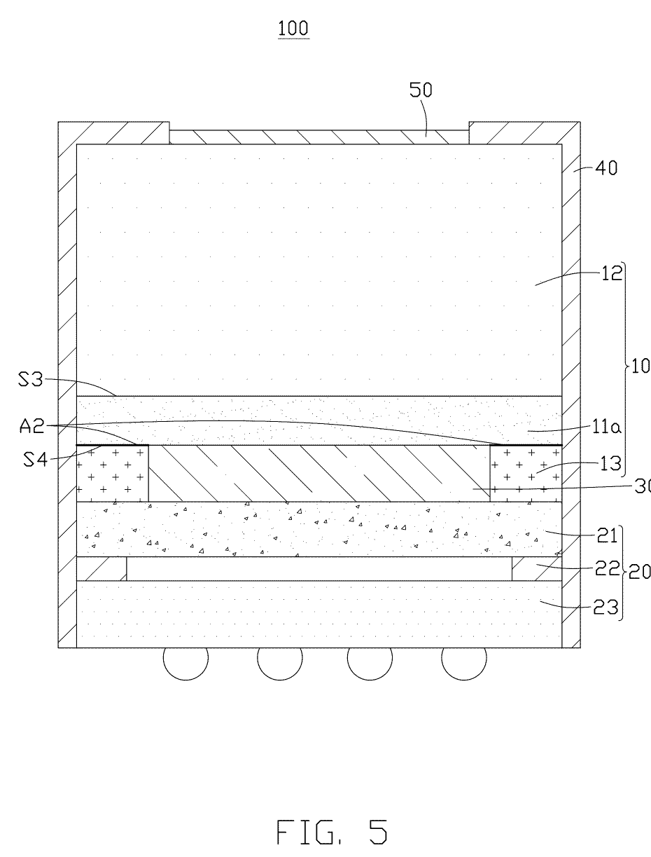

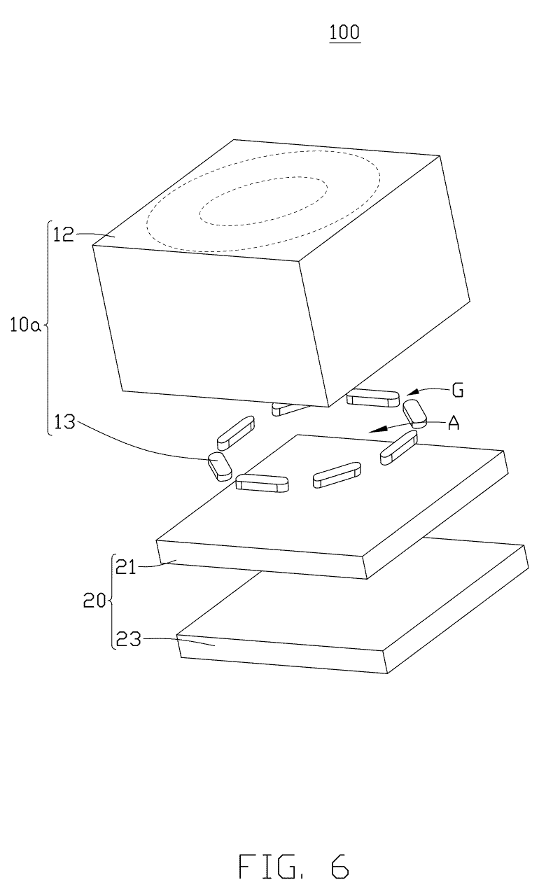

FIG. 5 is a cross-sectional schematic diagram of an optoelectronic module 100 according to an embodiment of the present disclosure. FIG. 6 is an exploded schematic diagram of an optoelectronic module 100 according to an embodiment of the present disclosure. It should be noted that some elements of the optoelectronic module 100 (such as the adhesive layer 30) are omitted in FIG. 6.

As shown in FIGS. 5 and 6, the optoelectronic module 100 includes a lens unit 10a and an optoelectronic component 20. The lens unit 10a includes a unit substrate 11a, a lens 12, and a supporting structure 13. The unit substrate 11a can be obtained by, but not limited to, cutting the wafer-level substrate 11. Both the lens 12 and the supporting structure 13 are located on the unit substrate 11a. A projection of the supporting structure 13 on the unit substrate 11a at least partially overlaps with a projection of the lens 12 on the unit substrate 11a. The side of the lens unit 10a where the supporting structure 13 is located is bonded to the optoelectronic component 20.

In some embodiments, an overlapping area A2 (Bolded in FIG. 5) is formed by overlapping the projection of the supporting structure 13 on the unit substrate 11a at least partially overlaps with a projection of the lens 12 on the unit substrate 11a, the overlapping area A2 is configured to compensate for the tilt angle of the optical axis of the lens 12.

In some embodiments, the boundary of the overlapping area A2 coincides with the boundary of the projection of the supporting structure 13 on the unit substrate 11a.

In some embodiments, the overlapping area A2 partially overlaps the projection of the supporting structure 13 on the unit substrate 11a.

Specifically, the lens 12 and the supporting structure 13 are located on opposite sides of the unit substrate 11a, respectively. The unit substrate 11a includes a third surface S3 and a fourth surface S4 opposite to the third surface S3. The lens 12 is located on the third surface S3, and the supporting structure 13 is located on the fourth surface S4.

In other embodiments, the supporting structure 13 and the lens 12 are located on the same side of the unit substrate 11a, with the supporting structure 13 positioned at the edge of the corresponding lens 12 to compensate for the optical axis tilt angle of the corresponding lens 12.

The optoelectronic module 100 further includes an adhesive layer 30. The adhesive layer 30 is located between the lens unit 10a and the optoelectronic component 20. The adhesive layer 30 is at least located within an area A enclosed by the ring structure of the supporting structure 13. The adhesive layer 30 is light-transmitting, and the refractive index of the adhesive layer 30 matches the refractive index of the lens 12.

In other embodiments, the supporting structure 13 has adhesiveness, and the lens unit 10a is directly bonded to the optoelectronic component 20 through the supporting structure 13. That is, the adhesive layer 30 can be omitted in the optoelectronic module 100.

In some embodiments, the supporting structure 13 includes a plurality of sub-portions 13a arranged at intervals along the circumferential direction of the lens 12, and the adhesive layer 30 also fills the gaps G between adjacent sub-portions 13a. The adhesive layer 30 fills the area A enclosed by the ring structure of the supporting structure 13, which helps to prevent foreign objects from entering this area A and affecting the imaging effect.

In some embodiments, the optoelectronic component 20 is a chip-level packaged image sensor. The optoelectronic component 20 includes a transparent cover plate 21, a sealing layer 22, and an image sensor 23. The sealing layer 22 is bonded to the peripheral areas of the cover plate 21 and the image sensor 23 to connect the two. The adhesive layer 30 fills the inside of the supporting structure 13 and the gaps G between adjacent sub-portions 13a to bond the unit substrate 11a of the lens unit 10a and the cover plate 21 of the optoelectronic component 20.

In some embodiments, the supporting structure 13 is a closed annular structure, and the adhesive layer 30 fills the area A hollowed out by the ring structure of the supporting structure 13 to bond the unit substrate 11a of the lens unit 10a and the cover plate 21 of the optoelectronic component 20.

In some embodiments, the optoelectronic component 20 further includes a light-shielding layer 40. The light-shielding layer 40 covers the sides of the lens unit 10a and the optoelectronic component 20 and partially extends to cover the surface of the lens unit 10a away from the optoelectronic component 20. The light-shielding layer 40 exposes part of the lens unit 10a to allow light to pass through.

In some embodiments, the optoelectronic component 20 further includes an anti-reflection layer 50. The anti-reflection layer 50 is located on the surface of the lens 12 of the lens unit 10a.

In some embodiments, the optoelectronic component 20 further includes a bandpass filter layer (not shown). The bandpass filter layer is located between the lens unit 10a and the image sensor 23. Specifically, the bandpass filter layer can be located on the lens 12 or on the cover plate 21.

In some embodiments, the optoelectronic module 100 can be, but is not limited to, a Time-of-Flight (ToF) module or a camera module.

The embodiments of the present disclosure also provide a lens unit 10a. The lens unit 10a includes a unit substrate 11a, a lens 12, and a supporting structure 13. The lens 12 is located on the unit substrate 11a. The supporting structure 13 is located on the unit substrate 11a. A projection of the supporting structure 13 on the unit substrate 11a at least partially overlaps with a projection of the lens 12 on the unit substrate 11a, to compensate for the optical axis tilt angle of the lens 12.

In some embodiments, the supporting structure 13 is located on the side of the unit substrate 11a away from the lens 12. That is, the supporting structure 13 and the lens 12 are located on opposite sides of the unit substrate 11a, respectively.

In some embodiments, the supporting structure 13 and the lens 12 are located on the same side of the unit substrate 11a, with the supporting structure 13 formed at the edge of the lens 12 to compensate for the optical axis tilt angle of the corresponding lens 12.

In summary, in the wafer-level lens, lens unit, and optoelectronic module of the embodiments of the present disclosure, the supporting structure can be formed at the wafer level. The supporting structure determines the tilt angle when the lens unit is attached to the surface of the optoelectronic component, thereby solving the optical axis tilt angle problems of a plurality of lenses at once, which significantly improves production efficiency compared to the related technology of adjusting lens tilt angles one by one in real time.

In the wafer-level lens, lens unit, and optoelectronic module of the embodiments of the present disclosure, by pre-generating supporting structures that compensate for the optical axis tilt angles of the corresponding lenses, the step of real-time adjustment of the tilt angle between the lens unit and the optoelectronic component in traditional active alignment methods is eliminated, greatly improving attachment speed.

Moreover, in the wafer-level lens, lens unit, and optoelectronic module of the embodiments of the present disclosure, due to the support from the supporting structure (the adhesive layer serves a bonding function, while tilt angle compensation relies mainly or entirely on the supporting structure), the requirements for the pre-curing strength of the packaging adhesive (i.e., the adhesive layer) are not high. This means that the pre-curing time can be shortened, further improving production efficiency.

Additionally, in the wafer-level lens, lens unit, and optoelectronic module of the embodiments of the present disclosure, the supporting structure provides the main physical support between the lens unit and the optoelectronic component. During the bonding process of the lens unit and the optoelectronic component, the packaging adhesive (i.e., the adhesive layer) between the supporting structure and the optoelectronic component is squeezed out as much as possible.

Therefore, the packaging adhesive (i.e., the adhesive layer) is basically at the same level as the supporting structure. Even if the packaging adhesive (i.e., the adhesive layer) inside the ring of the supporting structure shrinks during the curing process, the supporting structure can maintain the relative tilt angle between the lens and the optoelectronic component unchanged.

Furthermore, even if a small amount of adhesive is located between the supporting structure and the optoelectronic component, since this adhesive is very thin, the impact of its shrinkage on the tilt angle is negligible.

Therefore, the wafer-level lens, lens unit, and optoelectronic module of the embodiments of the present disclosure are beneficial for improving the precision of lens tilt angle compensation, thereby increasing production yield.

It is to be understood, even though information and advantages of the present exemplary embodiments have been set forth in the foregoing description, together with details of the structures and functions of the present exemplary embodiments, the disclosure is illustrative only. Changes may be made in detail, especially in matters of shape, size, and arrangement of parts within the principles of the present exemplary embodiments to the full extent indicated by the plain meaning of the terms in which the appended claims are expressed.

What is claimed is:

1. A wafer-level lens comprising:
a wafer-level substrate;
a plurality of lenses on the wafer-level substrate; and
a plurality of supporting structures on the wafer-level substrate, wherein each of the plurality of supporting structures is arranged to a corresponding lens of the plurality of lenses, an overlapping area is formed by overlapping a projection of the supporting structure on the wafer-level substrate at least partially overlaps with a projection of the corresponding lens on the wafer-level substrate, and the overlapping area is configured to compensate for a tilt angle of an optical axis of the corresponding lens.

2. The wafer-level lens according to claim 1, wherein the supporting structure has a non-uniform height distribution along a circumferential direction of the corresponding lens, the non-uniform height distribution is configured to match with a degree of the optical axis and a direction of the tilt angle of the optical axis of the corresponding lens to be compensated.

3. The wafer-level lens according to claim 1, wherein each of the plurality of supporting structures is a closed annular structure; or each of the plurality of supporting structures comprises a plurality of sub-portions spaced apart from each other along a circumferential direction of the corresponding lens.

4. The wafer-level lens according to claim 1, wherein the plurality of supporting structures and the plurality of lenses are on opposite sides of the wafer-level substrate, respectively.

5. The wafer-level lens according to claim 1, wherein the plurality of supporting structures and the plurality of lenses are on a same side of the wafer-level substrate.

6. The wafer-level lens according to claim 1, wherein each of the plurality of lenses is selected from at least one of:
a metalens having an array of nanostructures with sub-wavelength dimensions;
a diffractive optical lens with predetermined phase modulation characteristics;
a Fresnel lens having a plurality of concentric ring structures, the plurality of concentric ring structures forming a stepped refractive surface;
a gradient refractive index lens having a refractive index distribution continuously varying from a center to an edge; or
a microlens array having a predetermined radius of curvature and refractive index.

7. A lens unit comprising:
a unit substrate;
a lens on the unit substrate; and
a supporting structure on the unit substrate, wherein an overlapping area is formed by overlapping a projection of the supporting structure on the unit substrate at least partially overlaps with a projection of the lens on the unit substrate, and the overlapping area is configured to compensate for a tilt angle of an optical axis of the lens.

8. The lens unit according to claim 7, wherein the supporting structure has a non-uniform height distribution along a circumferential direction of the lens, the non-uniform height distribution is configured to match with a degree of the optical axis and a direction of the tilt angle of the optical axis of the lens to be compensated.

9. The lens unit according to claim 7, wherein the supporting structure is a closed annular structure; or the supporting structure comprises a plurality of sub-portions spaced apart from each other along a circumferential direction of the lens.

10. The lens unit according to claim 7, wherein the supporting structure and the lens are on opposite sides of the unit substrate, respectively; or the supporting structure and the lens are on a same side of the unit substrate.

11. The lens unit according to claim 7, wherein the lens is selected from at least one of:
a metalens having an array of nanostructures with sub-wavelength dimensions;
a diffractive optical lens with predetermined phase modulation characteristics;
a Fresnel lens with a plurality of concentric ring structures, the plurality of concentric ring structures forming a stepped refractive surface;
a gradient refractive index lens having a refractive index distribution continuously varying from a center to an edge; or
a microlens array having a predetermined radius of curvature and refractive index.

12. An optoelectronic module comprising:
an optoelectronic component; and
a lens unit comprising:
a unit substrate;
a lens on the unit substrate; and
a supporting structure on the unit substrate;
wherein the lens unit is bonded to the optoelectronic component at a side where the supporting structure is arranged, an overlapping area is formed by overlapping a projection of the supporting structure on the unit substrate at least partially overlaps with a projection of the lens on the unit substrate, and the overlapping area is configured to compensate for a tilt angle of an optical axis of the lens.

13. The optoelectronic module according to claim 12, wherein the supporting structure has a non-uniform height distribution along a circumferential direction of the lens, the non-uniform height distribution is configured to match with a degree of the optical axis and a direction of the tilt angle of the optical axis of the lens to be compensated.

14. The optoelectronic module according to claim 12, wherein the supporting structure is a closed annular structure; or the supporting structure comprises a plurality of sub-portions spaced apart from each other along a circumferential direction of the lens.

15. The optoelectronic module according to claim 12, wherein the supporting structure and the lens are on opposite sides of the unit substrate, respectively; or the supporting structure and the lens are on a same side of the unit substrate.

16. The optoelectronic module according to claim 12, wherein the lens is selected from at least one of:
a metalens having an array of nanostructures with sub-wavelength dimensions;
a diffractive optical lens with predetermined phase modulation characteristics;
a Fresnel lens with a plurality of concentric ring structures, the plurality of concentric ring structures forming a stepped refractive surface;
a gradient refractive index lens having a refractive index distribution continuously varying from a center to an edge; or
a microlens array having a predetermined radius of curvature and refractive index.

17. The optoelectronic module according to claim 12, wherein the supporting structure has adhesiveness, and the lens unit is directly bonded to the optoelectronic component through the supporting structure.

18. The optoelectronic module according to claim 12 further comprising an adhesive layer, wherein the lens unit is bonded to the optoelectronic component through the adhesive layer, the adhesive layer is at least located within an area enclosed by the supporting structure, the adhesive layer is light-transmitting, and a refractive index of the adhesive layer matches a refractive index of the lens.

19. The optoelectronic module according to claim 18, wherein the supporting structure comprises a plurality of sub-portions spaced apart from each other along a circumferential direction, the adhesive layer is further in gaps between adjacent sub-portions of the plurality of sub-portions.

20. The optoelectronic module according to claim 12, wherein the optoelectronic component is a chip-level packaged image sensor.
